(19) United States
(12) Patent Application Publication
(10) Pub. No.: US 2024/0055311 A1
(43) Pub. Date: Feb. 15, 2024

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yueh-Ting Lin, Taipei City (TW); Hua-Wei Tseng, New Taipei City (TW); An-Jhih Su, Taoyuan City (TW); Ming-Shih Yeh, Hsinchu County (TW); Der-Chyang Yeh, Hsin-Chu (TW)

(73) Assignee: Taiwan Semiconductor Manufacturing Company, Ltd., Hsinchu (TW)

(21) Appl. No.: 17/887,499

(22) Filed: Aug. 14, 2022

(51) Int. Cl. H01L 23/31; H01L 23/498; H01L 23/00; H01L 21/463

(52) U.S. Cl. CPC H01L 23/3157; H01L 23/49816; H01L 24/32; H01L 24/05; H01L 21/463; H01L 2924/15311; H01L 2224/32146; H01L 2224/02373

(57) ABSTRACT

A semiconductor structure includes a package, an electrical device and an underfill material. The package includes a redistribution structure and at least one die, and the at least one die is disposed on a first side of the redistribution structure. The electrical device is disposed on a second side of the redistribution structure, the electrical device has a top surface and a bottom surface opposite to each other, and the top surface faces the redistribution structure. The underfill material is disposed between the top surface and the redistribution structure and extending toward the bottom surface, the underfill material has an end surface corresponding to the bottom surface, and the end surface is a flat surface. In addition, a manufacturing method of the semiconductor structure is also provided.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), and package on package (PoP) devices. Some 3DICs are prepared by placing chips over chips on a semiconductor wafer level. The 3DICs provide improved integration density and other advantages, such as faster speeds and higher bandwidth, because of the decreased length of interconnects between the stacked chips. However, there are many challenges related to 3DICs. One challenge is the creeping of the underfill material. For example, in a condition that an underfill material is formed between an integrated passive device (IPD) and a corresponding fan-out package, the underfill material may unexpectedly creep along a side wall of the IPD and further onto a bottom surface of the IPD. Another challenge is a height restriction of the ball grid array (BGA). For example, for preventing the IPD from being crushed with a main logic board, a height of the BGA is restricted to be enough to support the main logic board away from the IPD.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional views of a semiconductor structure in accordance with some embodiments.

FIG. 2 is an enlarge view of a partial region of the semiconductor structure of FIG. 1.

FIG. 3 is an enlarge view of a region A of the electrical device and the underfill material of FIG. 2.

FIG. 4 is a cross-sectional views of a semiconductor structure in accordance with some embodiments.

FIG. 5 is a cross-sectional views of a semiconductor structure in accordance with some embodiments.

FIG. 6 is a cross-sectional views of a semiconductor structure in accordance with some embodiments.

FIG. 7A to FIG. 7D are cross-sectional views of a method of forming a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

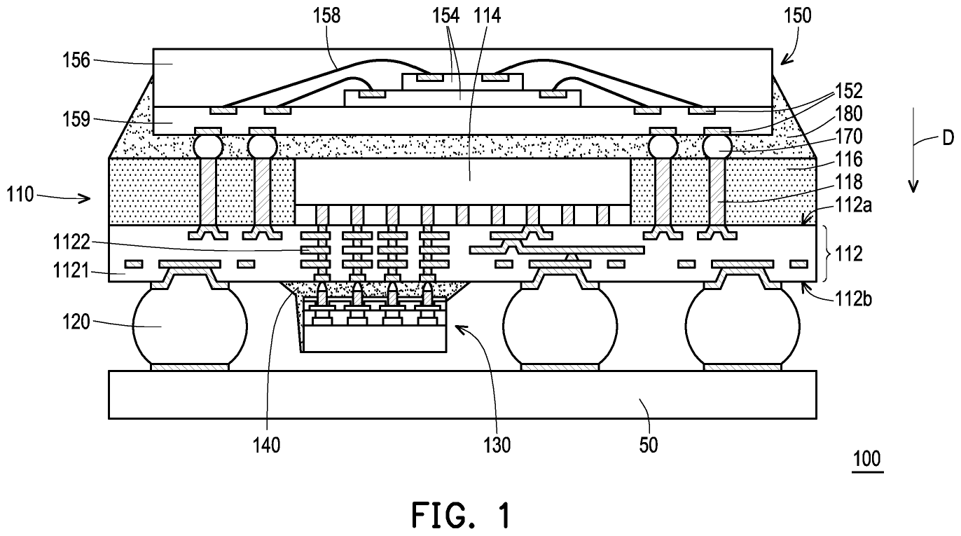

FIG. 1 is a cross-sectional views of a semiconductor structure in accordance with some embodiments. Referring to FIG. 1, the semiconductor structure 100 includes a package 110 and a plurality of conductive components 120. The package 110 is, for example, an integrated fan-out (InFO) semiconductor package and includes a redistribution structure 112, at least one die (one die 114 is illustrated) and an encapsulant 116. The redistribution structure 112 includes one or more layers of electrically conductive features (e.g., conductive lines/vias 1122) formed in one or more dielectric layer (e.g., dielectric layer 1121). The die 114 is disposed on a first side 112a of the redistribution structure 112, and the encapsulant 116 is formed around the die 114.

The encapsulant 116 includes a molding compound such as epoxy, a photo-sensitive material such as polybenzoxazole (PBO), polyimide (PI) or benzocyclobutene (BCB), a combination thereof or the like. The conductive components 120 are disposed on a second side 112b of the redistribution structure 112 for being connected to a substrate 50. The conductive components 120 are, for example, a ball grid array (BGA) or other types of conductive components, and the disclosure is not limited thereto. The substrate 50 is, for example, a main logic board or other types of substrates, and the disclosure is not limited thereto.

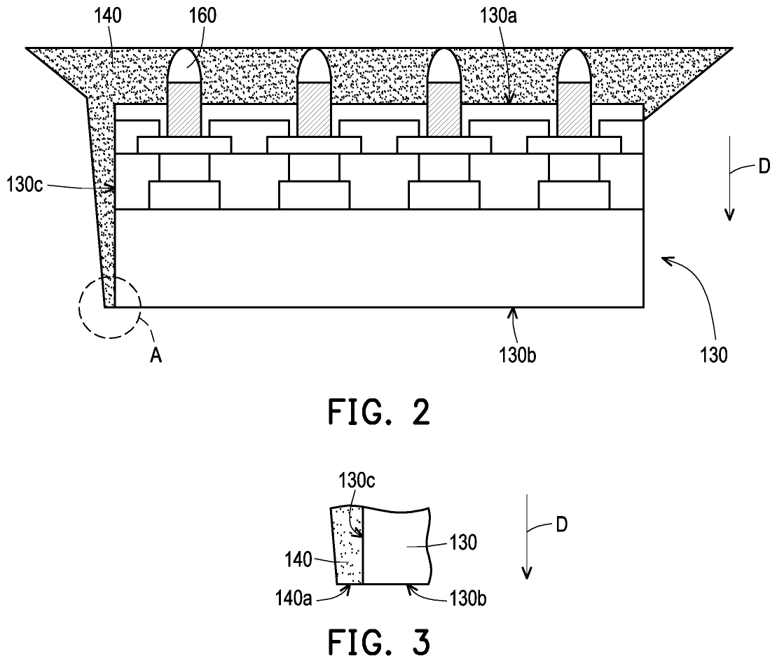

FIG. 2 is an enlarge view of a partial region of the semiconductor structure of FIG. 1. Referring to FIG. 1 and FIG. 2, the semiconductor structure 100 further includes an electrical device 130 and an underfill material 140. The electrical device 130 is, for example, an integrated passive device (IPD) and is disposed on the second side 112b of the redistribution structure 112. The electrical device 130 is electrically connected to the redistribution structure 112 through conductive components 160, such as solder joints. Each of the conductive components 120 has enough height to support the substrate 50 away from the electrical device 140, such that he electrical device 140 is located between the substrate 50 and the redistribution structure 112 without contacting the substrate 50.

The electrical device 130 has a top surface 130a and a bottom surface 130b opposite to each other, and the top surface 130a faces the redistribution structure 112. The underfill material 140 is disposed between the top surface 130a of the electrical device 130 and the redistribution structure 112, so as to fill a gap between the top surface 130a and the redistribution structure 112 and encapsulate the conductive components 160. In addition, the underfill material 140 extends along a side wall 130c of the electrical device 130 toward the bottom surface 130b of the electrical device 130, which may be due to a phenomenon that the underfill material 140 unexpectedly creeps from the top surface 130a toward the bottom surface 130b during an underfill-forming process.

FIG. 3 is an enlarge view of a region A of the electrical device and the underfill material of FIG. 2. Referring to FIG. 3, the underfill material 140 has an end surface 140a corresponding to the bottom surface 130b of the electrical device 130, and the end surface 140a is a flat surface. Specially, the end surface 140a of the underfill material 140 and the bottom surface 130b of the electrical device 130 are, for example, coplanar. That is, the underfill material 140 extends along the side wall 130c without creeping onto the bottom surface 130b of the electrical device 130. Accordingly, a total thickness of the electrical device 130 and the underfill material 140 along a direction D perpendicular to the bottom surface 130b would not be unexpectedly increased due to the formation of the underfill material 140. In other embodiments, the end surface 140a of the underfill material 140 and the bottom surface 130b of the electrical device 130 may not be formed to be coplanar, while a distance between the end surface 140a of the underfill material 140 and the bottom surface 130b of the electrical device 130 along the direction D is, for example, less than 5 micrometers.

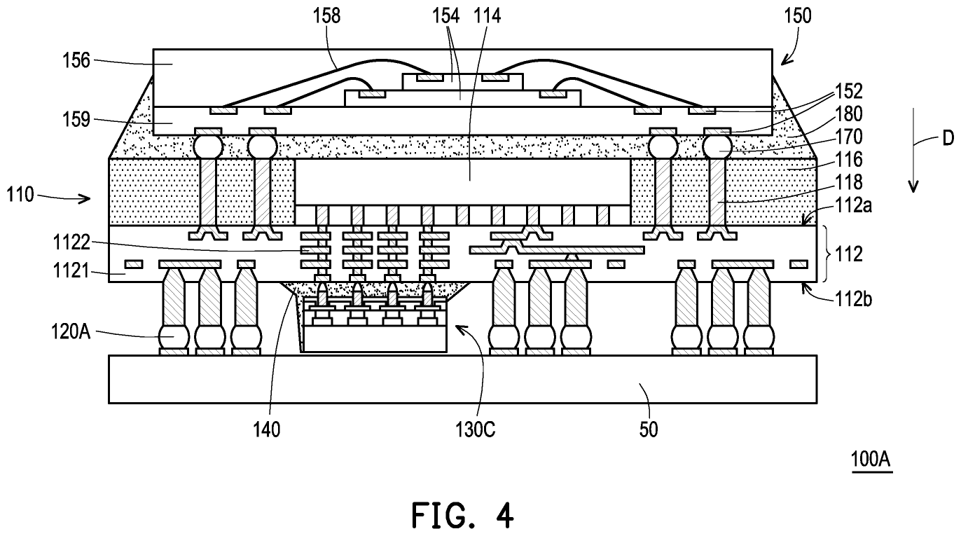

Since the total thickness of the electrical device 130 and the underfill material 140 could be reduced as described above, the height of the conductive components 120 could be reduced correspondingly. Therefore, the height of the whole semiconductor structure 100 is reduced. In addition, other types of conductive components with relatively small height may be applied to the semiconductor structure 100. FIG. 4 is a cross-sectional views of a semiconductor structure in accordance with some embodiments. For example, the conductive components 120A of the semiconductor structure 100A shown in FIG. 4 are, for example, controlled collapse chip connection (C4) bumps, which has smaller height than that of BGA. The arrangement of other components and/or structures in FIG. 4 are the same as or similar to that in FIG. 1, which will not be described repeatedly.

In the embodiments of FIG. 1 and FIG. 4, the semiconductor structure 100 further includes another package 150 stacking on the package 110 to form a package-on-package (POP) structure. Correspondingly, the package 110 further includes a plurality of conductive pillars 118 for electrically to the conductive pads 152 of the package 150 through conductive components 170. The encapsulant 116 is formed around the conductive pillars 118. An underfill material 180 is formed between the package 110 and the package 150, so as to fill a gap between the package 110 and the package 150 and encapsulate the conductive components 170.

The package 150 includes dies 154 (e.g., memory dies), an encapsulant 156, bonding wires 158 and a substrate 159. The dies 154 stacks on the substrate 159 and are electrically connected to the conductive pads 152 through the bonding wires 158. The encapsulant 156 is formed around the dies 154 and the bonding wires 158. In some embodiments, the substrate 159 includes silicon, gallium arsenide, silicon on insulator (“SOI”) or other similar materials. In some embodiments, the substrate 159 is a multiple-layer circuit board. In some embodiments, the substrate 159 includes bismaleimide triazine (BT) resin, FR-4 (a composite material composed of woven fiberglass cloth with an epoxy resin binder that is flame resistant), ceramic, glass, plastic, tape, film, or other supporting materials. The substrate 159 may include conductive features (e.g., conductive lines and vias, not shown) formed in/on the substrate 159. The encapsulant 156 includes a molding compound such as epoxy, a photo-sensitive material such as polybenzoxazole (PBO), polyimide (PI) or benzocyclobutene (BCB), a combination thereof or the like.

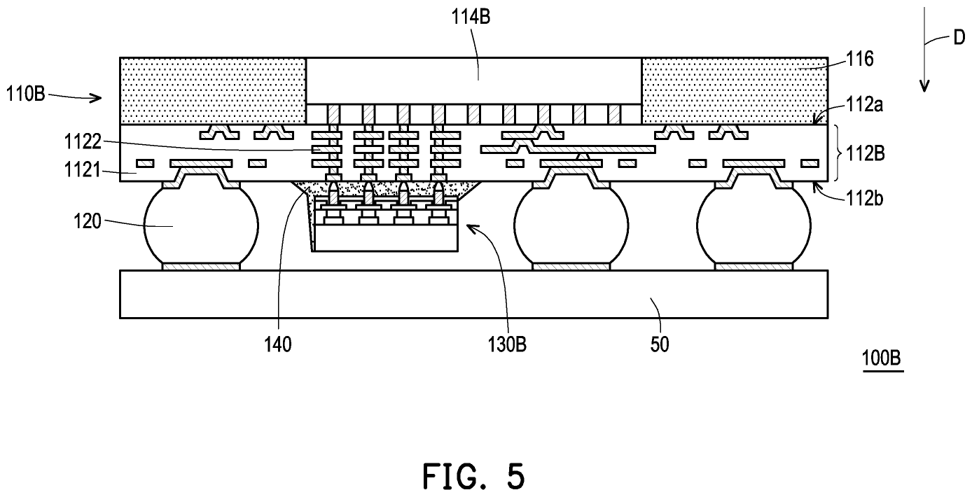

FIG. 5 is a cross-sectional views of a semiconductor structure in accordance with some embodiments. The difference between the semiconductor structure 100B in FIG. 5 and the semiconductor structure 100 in FIG. 1 is that, the package 110B is arranged without stacking another package thereon. The arrangement of the redistribution structure 112B, the die 114B, the electrical device 130B and other relative components and/or structures in FIG. 5 are the same as or similar to that in FIG. 1, which will not be described repeatedly.

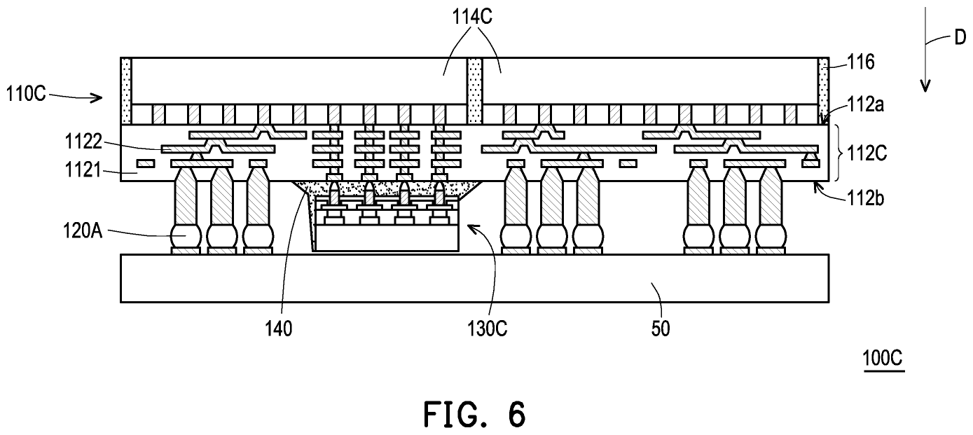

FIG. 6 is a cross-sectional views of a semiconductor structure in accordance with some embodiments. The difference between the semiconductor structure 100C in FIG. 6 and the semiconductor structure 100A in FIG. 4 is that, the package 110C is arranged without stacking another package thereon. In addition, the package 110C is, for example, a multi-die package which includes two or more dies 114 (two dies 114 are shown). The arrangement of the redistribution structure 112C, the die 114C, the electrical device 130C and other relative components and/or structures in FIG. 6 are the same as or similar to that in FIG. 1, which will not be described repeatedly.

In some embodiments, the conductive components 120 (BGA) shown in FIG. 1 and FIG. 5 may be applied to the semiconductor structure 100C in FIG. 6, the conductive components 120A (C4 bumps) shown in FIG. 4 and FIG. 6 may be applied to the semiconductor structure 100B in FIG. 5. In addition, other types of conductive components may be applied to the semiconductor structures 100, 100A, 100B and 100C, and the disclosure is not limited thereto.

The method of forming a semiconductor structure (such as the semiconductor structure 100, 100A, 100B or 100C described above) in accordance with some embodiments will be described as follows.

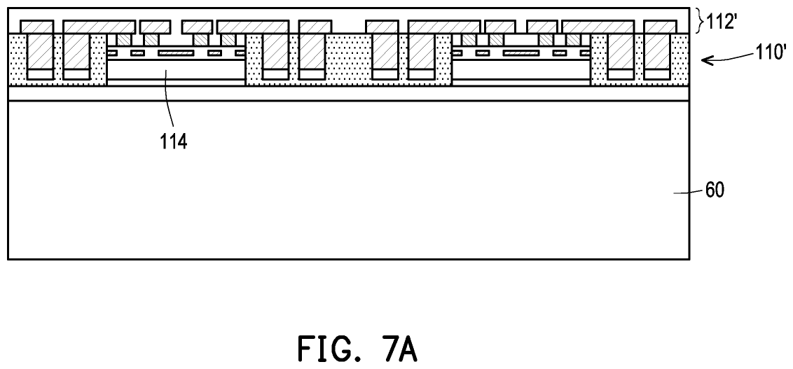

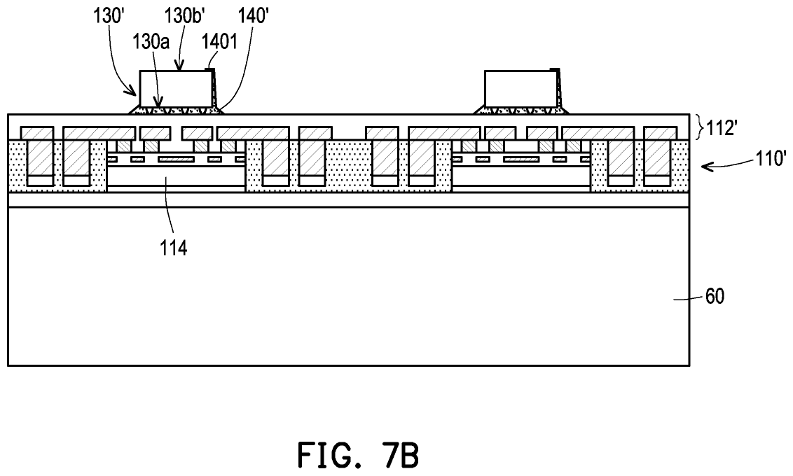

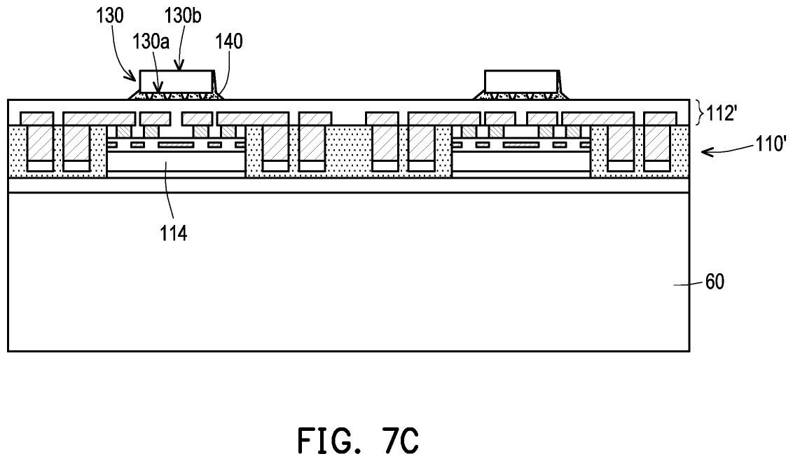

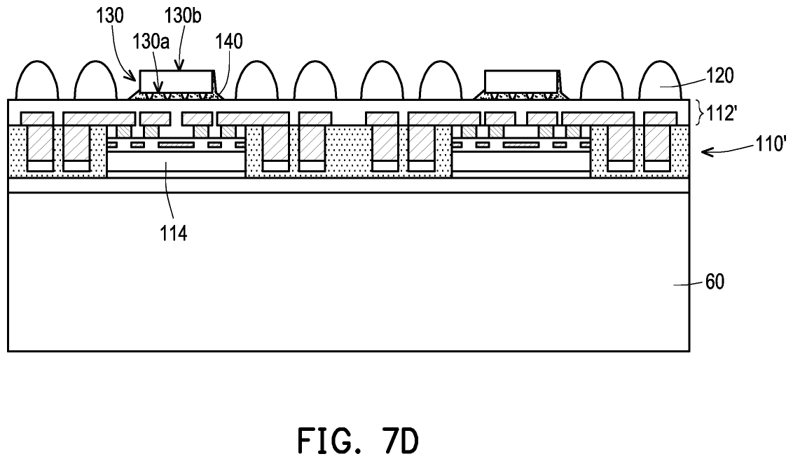

FIG. 7A to FIG. 7D are cross-sectional views of a method of forming a semiconductor structure in accordance with some embodiments. First, a package 110′ is provided on a carrier 60 as shown in FIG. 7A. The package 110′ is, for example, a package structure layer to be singularized for forming a plurality of the package 110, 110A, 110B or 110C described above, wherein the redistribution structure 112′ is, for example, corresponding to the redistribution structure 112, 112B or 112C described above, and the die 114 is, for example, corresponding to the die 114, 114B or 114C described above. Then, electrical devices 130′ are disposed on the package 110′ and underfill materials 140′ are formed between the top surface 130a of the electrical devices 130′ and the package 110′ as shown in FIG. 7B. Each of the electrical device 130′ has a top surface 130a and a bottom surface 130b′ opposite to each other, the top surface 130a faces the package 110′, and the underfill material 140′ extends toward the bottom surface 130b′ of the electrical device 130′ and includes a creeping portion 1401 at least partially located on the bottom surface 130b′.

Referring to FIG. 7C, a removing step is performed. The removing step is performed, for example, by a grinding process in which the creeping portion 1401 and a part of the electrical device 130′ at the bottom surface 130b′ are removed, such that thinner electrical devices 130 with ground bottom surfaces 130b and ground underfill materials 140 are formed. After the removing step is performed, an end surface (i.e. the end surface 140a shown in FIG. 3) of the underfill material 140 is a flat surface. Specially, the end surface 140a of the underfill material 140 and the bottom surface 130b of the electrical device 130 are, for example, coplanar. That is, the underfill material 140 extends along the side wall 130c without creeping onto the bottom surface 130b of the electrical device 130. Accordingly, a total thickness of the electrical device 130 and the underfill material 140 along a direction D perpendicular to the bottom surface 130b would not be unexpectedly increased due to the formation of the underfill material 140. In other embodiments, the end surface 140a of the underfill material 140 and the bottom surface 130b of the electrical device 130 may not be formed to be coplanar, while a distance between the end surface 140a of the underfill material 140 and the bottom surface 130b of the electrical device 130 along the direction D is, for example, less than 5 micrometers.

After the removing step is performed, a plurality of conductive components 120 are formed on the package 110′ as shown in FIG. 7D. Since the conductive components 120 are formed after the electrical device 130′ and the underfill materials 140′ are ground, the grinding process would not unexpectedly performed on the conductive components 120. In FIG. 7D, the conductive components 120 are illustrated as a BGA, which can be replaced by C4 bumps or other types of conductive components, and the disclosure is not limited thereto. Then, a singularization process may be performed on the structure shown in FIG. 7D and the carrier 60 may be debonded, such that a semiconductor structure (e.g. at least a part of the semiconductor structure 100, 100A, 100B or 100C described above) is formed.

In accordance with some embodiments, a semiconductor structure includes a package, an electrical device and an underfill material. The package includes a redistribution structure and at least one die, and the at least one die is disposed on a first side of the redistribution structure. The electrical device is disposed on a second side of the redistribution structure, the electrical device has a top surface and a bottom surface opposite to each other, and the top surface faces the redistribution structure. The underfill material is disposed between the top surface and the redistribution structure and extending toward the bottom surface, the underfill material has an end surface corresponding to the bottom surface, and the end surface is a flat surface.

In accordance with some embodiments, a semiconductor structure includes a package, an electrical device and an underfill material. The package includes a redistribution structure and at least one die, and the at least one die is disposed on a first side of the redistribution structure. The electrical device is disposed on a second side of the redistribution structure, the electrical device has a top surface and a bottom surface opposite to each other, and the top surface faces the redistribution structure. The underfill material is disposed between the top surface and the redistribution structure and extending toward the bottom surface, the underfill material has an end surface corresponding to the bottom surface, and a distance between the end surface and the bottom surface along a direction perpendicular to the bottom surface is less than 5 micrometers.

In accordance with some embodiments, a manufacturing method of a semiconductor structure includes at least the following steps. A package is provided on a carrier. An electrical device is disposed on the package, wherein the electrical device has a top surface and a bottom surface opposite to each other, and the top surface faces the package. An underfill material is formed between the top surface and the package, wherein the underfill material extends toward the bottom surface and includes a creeping portion at least partially located on the bottom surface. A removing step is performed, in which the creeping portion and a part of the electrical device at the bottom surface are removed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a package comprising a redistribution structure and at least one die, wherein the at least one die is disposed on a first side of the redistribution structure;
an electrical device disposed on a second side of the redistribution structure, wherein the electrical device has a top surface and a bottom surface opposite to each other, and the top surface faces the redistribution structure; and
an underfill material disposed between the top surface and the redistribution structure and extending toward the bottom surface, wherein the underfill material has an end surface corresponding to the bottom surface, and the end surface is a flat surface.

2. The semiconductor structure of claim 1, wherein the underfill material extends without creeping onto the bottom surface.

3. The semiconductor structure of claim 1, wherein the end surface and the bottom surface are coplanar.

4. The semiconductor structure of claim 1, wherein the electrical device is an integrated passive device (IPD).

5. The semiconductor structure of claim 1, further comprising a plurality of conductive components, wherein the conductive components are disposed on the second side of the redistribution structure for being connected to a substrate, such that the electrical device is located between the substrate and the redistribution structure without contacting the substrate, wherein the conductive components comprises a ball grid array (BGA) or a plurality of controlled collapse chip connection (C4) bumps.

6. The semiconductor structure of claim 1, further comprising another package stacking on the package to form a package-on-package (POP) structure.

7. The semiconductor structure of claim 1, wherein the package comprises a multi-die package.

8. A semiconductor structure, comprising:
a package comprising a redistribution structure and at least one die, wherein the at least one die is disposed on a first side of the redistribution structure;
an electrical device disposed on a second side of the redistribution structure, wherein the electrical device has a top surface and a bottom surface opposite to each other, and the top surface faces the redistribution structure; and
an underfill material disposed between the top surface and the redistribution structure and extending toward the bottom surface, wherein the underfill material has an end surface corresponding to the bottom surface, and a distance between the end surface and the bottom surface along a direction perpendicular to the bottom surface is less than 5 micrometers.

9. The semiconductor structure of claim 8, wherein the underfill material extends without creeping onto the bottom surface.

10. The semiconductor structure of claim 8, wherein the end surface and the bottom surface are coplanar.

11. The semiconductor structure of claim 8, wherein the electrical device is an integrated passive device (IPD).

12. The semiconductor structure of claim 8, further comprising a plurality of conductive components, wherein the conductive components are disposed on the second side of the redistribution structure for being connected to a substrate, such that the electrical device is located between the substrate and the redistribution structure without contacting the substrate, wherein the conductive components comprises a ball grid array (BGA) or a plurality of controlled collapse chip connection (C4) bumps.

13. The semiconductor structure of claim 8, further comprising another package stacking on the package to form a package-on-package (POP) structure.

14. The semiconductor structure of claim 8, wherein the package comprises a multi-die package.

15. A manufacturing method of a semiconductor structure, comprising:
providing a package on a carrier;
disposing an electrical device on the package, wherein the electrical device has a top surface and a bottom surface opposite to each other, and the top surface faces the package;
forming an underfill material between the top surface and the package, wherein the underfill material extends toward the bottom surface and includes a creeping portion at least partially located on the bottom surface; and
performing a removing step, in which the creeping portion and a part of the electrical device at the bottom surface are removed.

16. The manufacturing method of claim 15, wherein the removing step is performed by a grinding process.

17. The manufacturing method of claim 15, further comprising:
forming a plurality of conductive components on the package after the removing step is performed.

18. The manufacturing method of claim 15, wherein the removing step comprises forming an end surface on the underfill material, wherein the end surface is a flat surface.

19. The manufacturing method of claim 15, wherein the removing step comprises forming an end surface on the underfill material, wherein a distance between the end surface and the bottom surface along a direction perpendicular to the bottom surface is less than 5 micrometers.

20. The manufacturing method of claim 15, wherein the removing step comprises forming an end surface on the underfill material, wherein the end surface and the bottom surface are coplanar.
